(19) United States
(12) Patent Application Publication
(10) Pub. No.: US 2009/0199057 A1
(43) Pub. Date: Aug. 6, 2009

(54) March DSS: Memory Diagnostic Test

(75) Inventors: Sultan M. Al-Harbi, (US); Fadel Noor, (US); Fadi M. Al-Turjman, (US)

Correspondence Address: FURR LAW FIRM, 2622 DEBOLT ROAD, UTICA, OH, 43080, US

(73) Assignee: UNIVERSITY OF KUWAIT

(21) Appl. No.: 12/023,036

(22) Filed: Jan. 31, 2008

(51) Int. Cl. G11C 29/00

(52) U.S. Cl. 714/718

(57) ABSTRACT

Diagnostic march tests are powerful tests that are capable of detecting, identifying and locating faults in memories. While March SS was published for detecting simple static faults, no test has been published for identifying all faults and locating their involved memory cells. In this report, we target all published simple static faults. We identify faults that can not be distinguished due to their analogous behavior, and we provide a new 46n diagnostic test for the rest named March DSS. March DSS is the first test that is capable of identifying all distinguishable march test and yet has a lower time complexity.

### FIELD OF THE INVENTION

The present invention relates to Diagnostic march tests which are tests that are capable of detecting and identifying the existing faults in computer memories. They are extremely important as they give the memory manufacturers a better understanding of the faults that are found in their final products. As a result, manufacturers can change their memory design and layout in order to avoid having the discovered faults in their products.

### BACKGROUND OF THE INVENTION

### Prior Art Reference and Discussion

The objective of this invention is to find a new efficient diagnostic march test that has the capability to detect and identify all realistic simple (i.e. not linked) static fault models that exist in the semiconductor Random Access Memories (RAMs). Such a test should provide different signatures for every fault in a fault list and be as short as possible.

Diagnostic march tests are used by manufacturers of memories in order to identify faults in their products. Identifying the faults makes it possible for them to check their memory design and change it to avoid having the same faults in future production.

By checking the available resources, including the IEEE/IEE data base, there are the following diagnostic tests in the literature:
1. Diagnostic test for SA, TF, CFid and CFin faults published in 1996 [1].
2. Diagnostic test for SA, TF, CFin, and CFst faults published in 2001 [2].
3. Diagnostic test for SA, TF, CFin, CFid and CFds faults published in 2004 [3].

### SUMMARY OF THE INVENTION

Diagnostic march tests are powerful tests that are capable of detecting, identifying and locating faults in computer semiconductor memories. While a March SS was published for detecting simple static faults, no test has been published for identifying all faults and locating their involved memory cells. The current invention targets all published simple static faults. It identifies faults that can not be distinguished due to their analogous behavior, and provides a new 46 n diagnostic test for the rest named March DSS. March DSS is the first test that is capable of identifying all distinguishable March test and yet has a lower time complexity.

The invention covers all memory simple static faults, except those that behave in the same manner and impossible to distinguish from each other. Compared with previously published tests, the invention has much higher fault coverage and yet significantly lower time complexity (46 n instead of the known 55 n test), making it superior.

### BRIEF DESCRIPTION OF THE DRAWINGS

The above and other aspects, features, and advantages of the present invention will be better and more fully understood by those skilled in the art with reference to the following detailed and more particular description of specific and preferred embodiments thereof, presented in conjunction with the following drawings to show how the same may be carried into effect, wherein:

FIG. 1 is a list of address decoder faults;

FIG. 2 displays the March C-Test;

FIG. 3 displays the 55 n test;

FIG. 4 displays the built-in-self-test circuit; and

FIG. 5 display a sample computer processing system.

### DETAILED DESCRIPTION OF BEST MODE FOR CARRYING OUT THE INVENTION

There will now be described, by way of example only, the best mode contemplated by the inventor for carrying out the invention. In the following description numerous specific details are set forth in order to provide a thorough understanding of the present invention.

It will be apparent however, to one skilled in the art, that the present invention may be practiced without limitation to these specific details. In other instances, well known methods and structures have not been described in detail so as not to unnecessarily obscure the present invention.

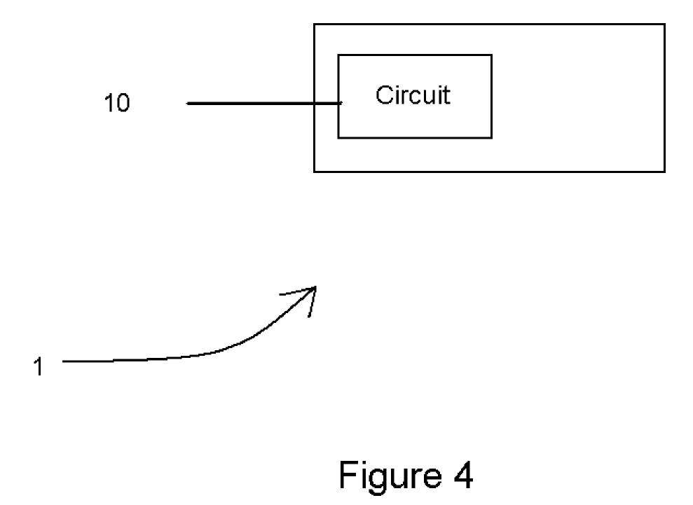

The current invention is a new test that is a March test that is capable of detecting and identifying the existing faults in computer semiconductor memories 1. It follows the march test structure and notation. It consists of a sequence of write and read operations. It can be used for testing memories whenever there is full access to their I/O pins. A uilt-in-self-test circuit 10 be easily built for integrating the invented test inside SoC systems 1 or testing memory modules as shown in FIG. 4.

The new test is of complexity 46 n, meaning that it takes 46 operations per memory cell under test. So, a memory module containing 1000 locations will take 46,000 operations to test it. This complexity is linear (in order of n) making it very reasonable.

The test verification process has shown that the new test successfully detects and identifies all targeted faults, except few single-cell faults that behave in the same manner and impossible to distinguish from each other.

March tests for memories are a class of tests that have been proven to be efficient due to their low time complexity and high fault coverage. Several march tests with different complexities have been developed.

The current invention considers a bit-oriented memory, i.e., a memory that has a single cell at every address. Faults can be either static or dynamic depending on the number of memory operations required for exciting them. Static faults can be excited by, at most, one memory operation (read or write), while dynamic faults are excited by more than one operation. The invention targets all memory static functional fault models (FFMs).

When two or more faults target the same cell in the memory, they are called linked faults. Otherwise, they are called unlinked (simple) faults.

In Single-cell FFMs these faults, only one memory cell is involved. They are shown in Table 1. The notation <y/z/w> is use, where y is a state or an operation to be performed on the victim cell z is the resulting faulty value in the cell, and w is the value returned by y, if y is a read operation. Notice that w is required only if the required operation on the victim cell is a read operation. The following is a detailed description of the targeted single-cell faults.
1. State fault (SF): In a short period after initialization and before accessing the memory cell v, the value of the memory cell flips. It consists of two possible cases: <0/1/-> and <1/0/->, where <0/1/-> refers to the case wherein the value of the cell changes from 0 to 1.
2. Transition faults (TF): A memory cell v accepts a transition in one direction but not in the other. It can be a ***arrow up*** transition fault, in which the memory cell changes from 1 to 0 but not from 0 to 1, or a ***down arrow*** transition fault.
3. Write Disturb faults (WDF): A non-transitive write operation to a memory cell v changes its value. It consists of two cases which are <0w0/***up arrow***/->, in which writing 0 to a cell that already contains 0 causes the cell to flip to 1, and <1w1/***down arrow***/>.
4. Read Destructive faults (RDF): A read to a cell causes the memory cell v to change its value and returns a wrong value. It could be <r0/***up arrow***/1>, in which reading 0 from a cell causes the cell to change to 1 and returns 1, or <r1/***down arrow***0>.
5. Deceptive Read Destructive faults (DRDF): A read operation to a memory cell v returns the correct value but it also flips the content of the cell. It could be <r0/***up arrow***/0>, in which reading 0 from a cell returns 0 but also changes the value of the cell to 1, and <r1/***down arrow***/1>.
6. Incorrect Read faults (IRF): The read operation returns a wrong value without changing the value of the memory cell v. It could be <r0/0/1>, in which reading 0 from a cell returns 1 while the cell keeps containing its 0 value, and <r1/1/0>.
7. Stuck-At faults (SAFs): A memory cell v has a value 0 (SA-0) or 1 (SA-1) that never changes.
8. Stuck Open fault (SOF): A memory cell v is not accessible and hence performing a read operation on it returns the value that was read during the last read operation to any cell in the same column.
9. Data Retention fault (DRF) [3]: The value of a memory cell v flips when not accessed for a long time. It can be DR-0, where 1 in the faulty cell becomes 0 after a long time, or DR-1. The required waiting time for the fault to manifest can be specified using SPICE simulation for the targeted design.

TABLE 1
List of single-cell faults[6]

| # | FFM | Fault primitives |
|---|---|---|
| 1 | SF | <1/0/—>, <0/1/—> |
| 2 | TF | <0w1/0/—>, <1w0/1/—> |
| 3 | WDF | <0w0/↑/—>, <1w1/↓/—> |
| 4 | RDF | <r0/↑/1>, <r1/↓/0> |
| 5 | DRDF | <r0/↑/0>, <r1/↓/1> |
| 6 | IRF | <r0/0/1>, <r1/1/0> |

In Two-cell FFMs, it is possible that the state or the operation in one memory cell (coupling cell or aggressor) affects the value or the behavior of another memory cell (victim cell). For simplicity, a coupling cell is denoted by a and a victim cell by v in the rest of this report. With these faults, the notation is used <x,y/z/w>, where x is a state or an operation to be performed in the coupling cell, y is a state or an operation to be performed in the victim cell, z is the resulting faulty value or behavior in the victim cell, and w is the value returned by y if y is a read operation. Notice that w is required only if the required operation on the victim cell is a read operation. Table 2 provides the coupling faults. The following is the detailed description of the targeted coupling faults.
1. State coupling faults (CFst): The victim cell is forced to a certain value if the coupling cell has a certain value. No operation on the victim cell can change its value as long as the coupling cell has the exciting value. It could be one of four types: <0,0>, <0,1>, <1,0> or <1,1>.
2. Disturb coupling faults (CFds): A read or write operation at the coupling cell foces the victim cell to change to a certain value. The write operation could be a transitive or non-transitive write operation. This fault could be CFds-r, which are of sub-types <r0,1/***arrow down***/->, <r0,0/***arrow up***/->, <r1,1/***arrow down***/-> or <r1,1/***arrow up***/->, or CFds-w which are of sub-types <0w0, 1/***arrow down***/->, <0w0, 1/***arrow up***/->, <0w1, 1/***arrow down***/->, <0w1, 1/***arrow up***/->, <1w0, 1/***arrow down***/->, <1w0, 1/***arrow up***/->, <1w1, 1/***arrow down***/-> or <1w1, 1/***arrow up***/->, where <0w0, 1/***arrow down***/-> that writing 0 to the coupling cell that contains 0 forces the victim cell to change to 0.
3. Transition coupling faults (CFtf): The victim cell experiences a transition fault only if the coupling cell has a certain value. It could be one of four types: <0, 0w1/0/->, <0, 1w0/1/->, <1, 0w1/0/-> or <1, 1w0/1/->.
4. Write Destructive couple faults (CFwd): The victim cell experiences a write disturb fault only if the coupling cell has a certain value. It could be one of four types: <0, 0w0/***arrow up***/->, <0, 1w1/***arrow down***/->, <1, 0w0/***arrow up***/-> or <1, 1w1/***arrow down***/->.
5. Read Destructive coupling faults (CFrd): The victim cell experiences a read destructive fault only if the coupling cell has a certain value. It could be one of four types: <0,r0/***arrow up***/1>, <0,r1/***arrow down***/0>, <1,r0/***arrow up***/1> or <1,r1/***arrow down***/1>.
6. Deceptive Read Destructive coupling faults (CFdrd): The victim cell experiences a deceptive read destructive fault only if the coupling cell has a certain value. It could be one of four types: <0,r0/***arrow up***/0>, <0,r1/***arrow down***/1>, <1,r0/***arrow up***/0> or <1,r1/***arrow down***/1>.
7. Incorrect Read coupling faults (CFir): The victim cell experiences an incorrect read fault only if the coupling cell has a certain value. It could be one of four types: <0,r0/0/1>, <0,r1/1/0>, <1,r0/0/1> or <1,r1/1/0>.

TABLE 2
List of coupling faults [6]

| # | FFM | Fault primitives |
|---|---|---|
| 1 | CFst | <0; 0/1/—>, <0; 1/0/—>, <1; 0/1/—>, <1; 1/0/—> |
| 2 | CFds | <xwy; 0/↑/—>, <xwy; 1/↓/—>, <rx; 0/↑/—>, <rx; 1/↓/—> |
| 3 | CFtr | <0; 0w1/0/—>, <1; 0w1/0/—>, <0; 1w0/1/—>, |
| | | <1; 1w0/1/—> |
| 4 | CFwd | <0; 0w0/↑/—>, <1; 0w0/↑/—>, <0; 1w1/↓/—>, |
| | | <1; 1w1/↓/—> |
| 5 | CFrd | <0; r0/↑/1>, <1; r0/↑/1>, <0; r1/↓/0>, <1; r1/↓/0> |
| 6 | CFdrd | <0; r0/↑/0>, <1; r0/↑/0>, <0; r1/↓/1>, <1; r1/↓/1> |
| 7 | CFir | <0; r0/0/1>, <1; r0/0/1>, <0; r1/1/0>, <1; r1/1/0> |

In addition, considering inversion coupling faults (CFin) [8], where a transition in one memory cell (coupling cell: a) inverts the value of another memory cell (victim cell: v). In a <0w1,***double arrow***> coupling fault, a high transition in cell a inverts the value of cell v. A <1w0,***double arrow***> fault can be defined in a similar manner.

In the literature, idempotent coupling faults (CFid) are sometimes considered. They are a subset of CFds faults. So, it is sufficient to consider CFds faults only.

The notation for faults, “av” (or a<v) means that the aggressor is at an address that is less than the address of the victim cell. The notation “va” (a>v) means the opposite.

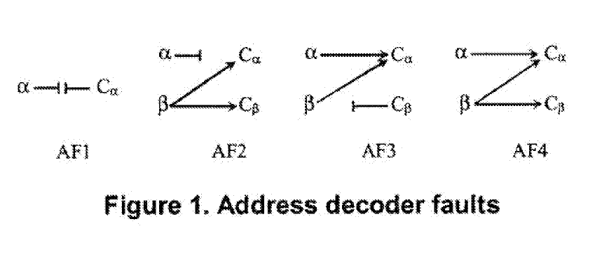

With Address decoder faults, the decoder used to select a memory cell has a fault that causes it to malfunction. The possible malfunctions are:
a) An address does not point to any location.
b) An address points to multiple locations.
c) No address points to a location.
d) Multiple addresses point to one location
   These four malfunctions result in the four address decoder (AD) faults shown in FIG. 1, where ***weird a thing*** and ***weird b thing*** denote addressed and C***weird a thing*** and C***weird b thing*** denote memory locations. A read to an address that is not pointing to any location returns a fixed value (like SA-0 or SA-1), while a read to an address that points to two memory cells returns the ANDing or ORing of the two values present in those cells.

March tests are a family of memory tests that are known for their high fault coverage and low time complexity. In the past, march tests were only used for detecting faults. They lacked the ability to identify the existing faults, meaning that the test was only able to ascertain whether or not a memory chip was faulty, without providing any information about the identity of the detected fault, when present. This situation changed when diagnostic march tests were discovered. With such tests, existing faults can now be identified and both the victim and aggressor cells can be located. With such information, it is possible to build a bit map of the memory showing the cells involved in any fault.

The Structure of march tests is as follows.

### Notation:

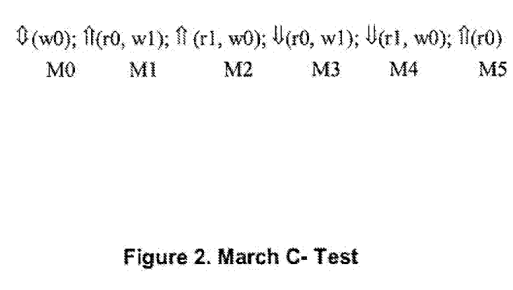

w0 is used to denote write 0 to the memory cell under test. w1 can be similarly defined.
r0 is used to denote read data from the cell under test, expect the value 0. r1 can be similarly defined.
A march element is a set of consecutive operations that are performed on one memory cell before moving to the next, until all locations are enumerated, such as ****arrow up***(r0, w1).
***arrow up*** is the direction of a march element and indicates some arbitrary, but fixed, order of traversing all memory cells, where each cell is visited exactly once. ***arrow down*** indicates a traversal of all memory cells in an order that is the opposite of that for ***arrow up*** ***double arrow*** indicates a traversal of all memory cells in either of the above two orders.
March elements are numbered, starting with M0 for the first march element, etc. A march test is a finite sequence of march elements [14]. A march test is called redundant if a test obtained by removing one or more operations from the test provides identical coverage of targeted faults. FIG. 2 shows March C-, which is a well known march test.

### 3.2. Diagnostic March Tests

Diagnostic march tests are march tests that provide different signatures for each targeted fault, and different signatures for the cases of a>v and a<v. The number of bits in the signature is equal to the number of read operations in the test. Each memory cell provides a signature. A ‘1’ in the signature means that the read operation to a memory cell returned a wrong value, i.e. different from the expected value. If the memory cell is fault-free or contains a fault that is not detected by the applied test, then all the signature bits will contain ‘0’, meaning that all the read operations have returned expected values. Table 4 shows the signatures for faults that result from applying March C-. Notice that the SA-0 fault has the signature 01010, which means that the second and fourth read operations in the test, which are r1 operations, have returned faulty values. Notice that only four of all the possible ninety faults have unique signatures while the rest group together into groups with unique group signatures. Hence, only four faults can be identified by applying March C-. By applying the March SS test, only 12 faults can be identified. The target is to have a test with a unique signature for every fault from the fault models discussed earlier.

TABLE 3
Signatures of March C-test

| Fault | Signature |
|---|---|
| SA-0, <1/0/—>, <0w1/0/—>, <r1/↓/0>, <r1/1/0>, <0, 1/0/—>ₐᵥ, <1, 1/0/—>ₐᵥ, <0, 1/0/—>ᵥₐ and <1, 1/0/—>ₐᵥ | 01010 |
| SA-1, <1/0/—>, <r0/↑/1>, <r0/0/1>, <0, 0/1/—>ₐᵥ and <0, 0/1/—>ᵥₐ | 10101 |
| <1w0/1/—>, <0; r0/↑/1>ₐᵥ and <0; r0/0/1>ₐᵥ | 00101 |
| <0w1, [symbol] >ₐᵥ | 10010 |
| <0w1; 1/↓/—>ₐᵥ, <1w0; 1/↓/—>ᵥₐ, <r0; 1/↓/—>ₐᵥ, <0; 0w1/0/—>ₐᵥ, <1; r1/↓/0>ₐᵥ, <1; r1/1/0>av, <r1; 1/↓/—>_{va,} | 00010 |
| <1; 0w1/0/—>ᵥₐ, <0; r1/↓/0>ᵥₐ and <0; r1/1/0>ᵥₐ | |
| <0w1; 0/↑/—>ₐᵥ, <1; r0/↑/1>ₐᵥand <1; r0/0/1>ₐᵥ | 10000 |
| <1w0; 1/↓/—>ₐᵥ, <0w1; 1/↓/—>ᵥₐ, <r1; 1/↓/—>ₐᵥ, <1; 0w1/0/—>ₐᵥ, <0; r1/↓/0>ₐᵥ, <0; r1/1/0>av, <r0; 1/↓/—>_{va, <0; 0w1/0/—>va} | 01000 |
| <1; r1/↓/0>ᵥₐ and <1; r1/1/0>ᵥₐ | |
| <1w0, [symbol] >ₐᵥ | 01001 |
| <1w0; 0/↑/—>ₐᵥ, <r1; 0/↑/—>ₐᵥ, <1; 1w0/1/—>ₐᵥ and <0; 1w0/1/—>ᵥₐ | 00001 |
| <1; 0/1/—>ₐᵥ, <r0; 0/↑/—>ₐᵥ, <0; r0/↑/1>ᵥₐ and <0; r0/0/1>ᵥₐ | 10001 |
| <0w1, [symbol] >ᵥₐ | 01100 |
| <0w1; 0/↑/—>ᵥₐ, <1w0; 0/↑/—>ᵥₐ, <1; 0/1/—>ᵥₐ, <0; 1w0/1—>ₐᵥ, <r0; 0/↑/—>ᵥₐ, <r1; 0/↑/—>ᵥₐ, <1; 1w0/1/—>ᵥₐ, | 00100 |
| <1; r0/↑/1>ᵥₐ and <1; r0/0/1>ᵥₐ | |
| <1w0, [symbol] >ᵥₐ | 00110 |

The current invention uses advanced techniques for generating the new diagnostic march test, named March DSS. It consists of only 46 operations divided on 16 march elements.

In the test generation process that we used in order to generate March DSS, we had to build two essential tools, which are the Diagnostic Test Verified (DTV) and the Diagnostic Test Redundancy Checker (DTRC). Given a test, the DTV tool simulates the memory in order to verify its correctness; while the DTRC tool verifies that it is irredundant (all operations are needed).

A 17 n diagnostic test for a small subset of the faults, namely SA, CFst, CFid, and CFin faults.

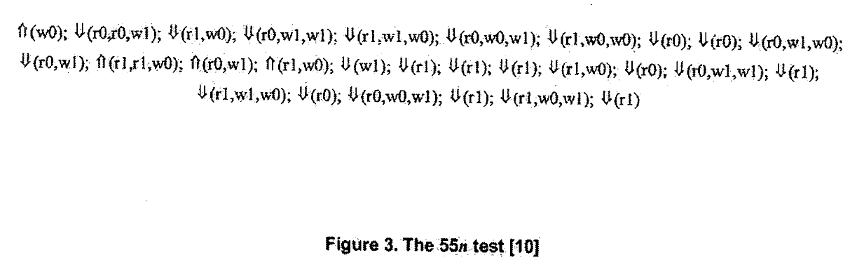

Two diagnostic march tests, a 55 n test (shown in FIG. 3) that was generated using a greedy-based algorithm, and a 52 n test that was generated using a simulation-based approach. The targeted faults were SAFs, TFs, CFin, CFid and CFds faults.

The 55 n test is actually capable of detecting and identifying all targeted faults.

Studies on the 52 n test show that the test fails in detecting some disturb coupling faults, meaning that the test is incomplete in terms of detecting faults, much less identifying them. Obviously, a diagnostic test should not just detect faults, but must also identify them. If a test fails in detecting a fault, it naturally faults in identifying it. The undetected targeted faults are: <1w1, 1>av and <1w1, 0>va. Notice that such non-transitive write operations were not considered as part of the CFds faults, and this could be the reason behind not detecting them.

Compared to prior art, the March DSS provides significant improvement in terms of fault coverage, time complexity and power consumption.

In terms of fault coverage, March DSS was proven to be able to identify all the 80 distinguishable faults, as shown in Table 4. However, by applying the a DTV tool to the 55 n test it was found out that it is able to identify only 31 of the 80 distinguishable faults. As a result, the March DSS has double the fault coverage of the 55 n test by 9 operations, leading to 16.4% improvement. Time complexity is a major issue when comparing between march tests. A test with lower time complexity requires less time when using ATE machines, which leads to lower cost for testing and a shorter time to hit the market.

In terms of power consumption, March DSS has fewer march elements; it consists of only 16 march elements while the 55 n test consists of 28 march elements. Each march element requires visiting all the memory locations, causing transitions in the address lines and leadings to hear dissipation. As a result, having fewer march elements leads to lower power consumption. Power consumption is a major issue in using march tests, especially when many memory modules present in one SoC are being tested concurrently. It is possible that the SoC under test will experience levels of heat that it would never experience in ordinary operation leading to failure of the system due to testing.

### Conclusion

The new invention, the March DSS provides significant improvement in terms of fault coverage, time complexity and power consumption.

The invention covers all memory simple static faults mentioned earlier, except those that behave in the same manner and impossible to distinguish from each other. Compared with previously published tests, the invention has much higher fault coverage and yet significantly lower time complexity (46 n instead of the known 55 n test), making it superior.

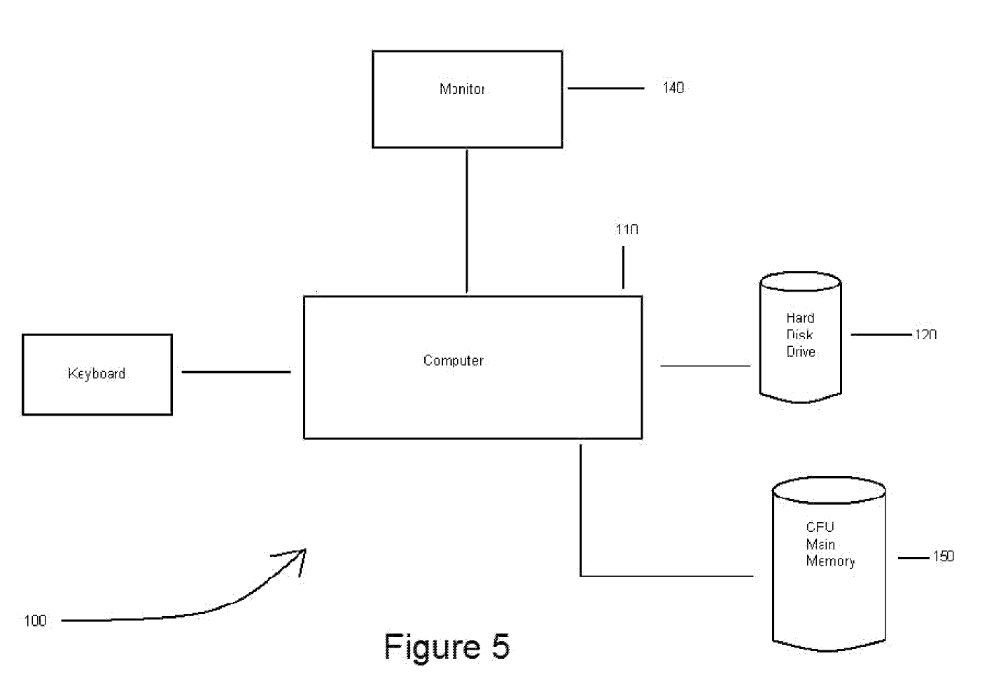

The invention can be implemented through a computing device 100. FIG. 5 is a block diagram showing a sample computing device 100 on which the present invention can run comprising a CPU 110, Hard Disk Drive 120, Keyboard 130, Monitor 140, CPU Main Memory 150 and a portion of main memory where the program resides and executes. A printer can also be included. Any general purpose computer with an appropriate amount of storage space is suitable for this purpose. Computer Devices like this are well known in the art and is not pertinent to the invention.

### Equivalents

From the foregoing description, one skilled in the art can easily ascertain the essential characteristics of this invention and, without departing from the spirit and scope thereof, can make various changes and modifications of the invention to adapt it to various usages and conditions. Such variations and changes may include, for example, altering the number of components in the housing or using equivalents. It is believed that such can be accomplished without excessive experimentation. In any case, any such variations are all claimed under the scope of this invention.

The methods of the present invention have been explained with reference to plurality of references the teachings of which are all incorporated herein by reference.

This invention has been described hereinabove, although with reference to a plurality of illustrative and preferred embodiments, it is to be understood that is in no way to be construed as limiting but only to provide examples. However, it is readily appreciated that, from reading this disclosure, the invention may be embodied in other specific forms without departing from the spirit or essential characteristics or attributes to bring modifications by replacing some elements of this invention as practiced by their equivalents, which would achieve that same goal thereof and accordingly reference should be made to the appended claims, rather than to the foregoing specification, as indicating the scope of the invention. Accordingly, those skilled in the art will recognize or be able to ascertain, using no more than routine experimentation, many equivalents to the specific embodiments and the scope of the invention being indicated by the appended claims described herein. Such equivalents, obvious variations, and all changes which come within the meaning and equivalency of the claims are therefore intended to be encompasses therein and are deemed covered by the claims of this invention.

From the foregoing description, one skilled in the art can easily ascertain the essential characteristics of this invention and, without departing from the spirit and scope thereof, can make various changes and modifications of the invention to adapt it to various usages and conditions. Such variations and changes may include, for example, altering the number of components in the housing or using equivalents. It is believed that such can be accomplished without excessive experimentation. In any case, any such variations are all claimed under the scope of this invention.

We claim:

1. A process to test faults in semiconductor memories comprising: a March test consisting of a sequence of write and read operations used to test memories whenever there is full access to their I/O pins performing 46 operations per memory cell under test.

2. A process according to claim 1 further comprising:
having 46 operations divided on 16 march elements.

3. A process according to claim 1 further comprising:
having a Diagnostic Test Verified (DTV) tool and a Diagnostic Test Redundancy Checker (DTRC) tool.

4. A process according to claim 3 further comprising:
having the DTV tool simulate the memory in order to verify its correctness.

5. A process according to claim 3 further comprising:
having the DTRC tool verify that the memory is irredundant.

6. A process according to claim 1 further comprising:
where said test consists of only 16 march elements.

7. A process according to claim 1 further comprising:
where each march element requires visiting all the memory locations, causing transitions in the address lines and leadings to hear dissipation.

8. A process according to claim 1 further comprising:
where said process is run on a computer processor.

9. A process to test faults in semiconductor memories comprising:
a March test consisting of a sequence of write and read operations used to test memories whenever there is full access to their I/O pins performing 46 operations per memory cell under test where said process is run on a computer processor.

10. A process according to claim 9 further comprising:
having 46 operations divided on 16 march elements.

11. A process according to claim 9 further comprising:
having a Diagnostic Test Verified (DTV) tool and a Diagnostic Test Redundancy Checker (DTRC) tool.

12. A process according to claim 11 further comprising:
having the DTV tool simulate the memory in order to verify its correctness.

13. A process according to claim 11 further comprising:
having the DTRC tool verify that the memory is irredundant.

14. A process according to claim 9 further comprising:
where said test consists of only 16 march elements.

15. A process according to claim 9 further comprising:
where each march element requires visiting all the memory locations, causing transitions in the address lines and leadings to hear dissipation.
